(19) United States
(12) Patent Application Publication
(10) Pub. No.: US 2008/0242066 A1
(43) Pub. Date: Oct. 2, 2008

(54) Method Of Manufacturing Semiconductor

(75) Inventors: Dale C. Jacobson, Salem, NH (US); Yoji Kawasaki, Toyonaka-City (JP)

Correspondence Address: PATENT ADMINISTRATOR;KATTEN MUCHIN ROSENMAN LLP, 2900 K Street NW, Suite 200, WASHINGTON, DC, 20007-5118, US

(73) Assignees: SEMIEQUIP INC., Billerica, MA (US); RENESAS TECHNOLOGY CORP., Tokyo (JP)

(21) Appl. No.: 11/577,572

(22) PCT Filed: Oct. 7, 2005
(86) PCT No.: PCT/US2005/036059

§ 371 Date: Jan. 16, 2008

Related U.S. Application Data
(60) Provisional application No. 60/621,112, filed on Oct. 22, 2004.

(51) Int. Cl. H01L 21/265

(52) U.S. Cl. 438/525; 257/E21.334

(57) ABSTRACT

A method of producing ultra shallow junctions (104) for PMOS transistors, which eliminates the need for pre-amorphization implants, is disclosed. The method utilizes dopant species, such as cluster ions, e.g., octadecaborane, B₁₈H₂₂. In accordance with the present invention, the pre-amorphizing step may be eliminated, greatly reducing cost per processed wafer. An appropriate process sequence has been suggested to take advantage of cluster ion implantation for PMOS manufacturing. In addition, the novel use of tilted implants for the source/drain extension and for pocket implants has been described.

### CROSS REFERENCE TO RELATED APPLICATIONS

This application claims the benefit and priority to U.S. Provisional Patent Application No. 60/621,112, filed on Oct. 22, 2004.

### 1. FIELD OF THE INVENTION

The present invention relates to integrated circuit manufacturing with enhanced throughput utilizing ultra-low energy boron implants with improved junction characteristics.

### 2. DESCRIPTION OF THE PRIOR ART

CMOS is the dominant integrated circuit technology in current use and its name denotes the formation of both N-channel and P-channel MOS transistors (Complementary MOS: both N and P) on the same chip. The success of CMOS is that circuit designers can make use of the complementary nature of the opposite transistors to create a better circuit, specifically one that draws less active power than alternative technologies. It is known that the N and P terminology is based on Negative and Positive (N-type semiconductor has negative majority carriers, and vice versa), and the N-channel and P-channel transistors are duplicates of each other with the type (polarity) of each region reversed. The fabrication of both types of transistors on the same substrate requires sequentially implanting an N-type impurity and then a P-type impurity, while protecting the other type of devices with a shielding layer of photoresist. It is also known that each transistor type requires regions of both polarities to operate correctly, but the implants which form the shallow junctions are of the same type as the transistor: N-type shallow implants into N-channel transistors and P-type shallow implants into P-channel transistors.

The fabrication of semiconductor devices involves, in part, the introduction of impurities into the semiconductor substrate to form doped regions. The impurity elements are selected to bond appropriately with the semiconductor material to create an electrical carrier and change the electrical conductivity of the semiconductor material. The electrical carrier can either be an electron (generated by N-type dopants) or a hole (generated by P-type dopants). The concentration of introduced dopant impurities determines the electrical conductivity of the resultant region. Many such N- and P-type impurity regions must be created to form transistor structures, isolation structures and other such electronic structures, which collectively function as a semiconductor device.

The conventional method of introducing dopants into a semiconductor substrate is by ion implantation. In ion implantation, a feed material containing the desired element is introduced into an ion source and energy is introduced to ionize the feed material, creating ions which contain the dopant element (for example, the elements ⁷⁵As, ¹¹B, ¹¹⁵In, ³¹P, or ¹²¹Sb. An accelerating electric field is provided to extract and accelerate the typically positively-charged ions, thus creating an ion beam. Then, mass analysis is used to select the species to be implanted, as is known in the art, and the ion beam is directed at a semiconductor substrate. The accelerating electric field gives the ions kinetic energy, which allows the ions to penetrate into the target. The energy and mass of the ions determine their depth of penetration into the target, with higher energy and/or lower mass ions allowing deeper penetration into the target due to their greater velocity. The ion implantation system is constructed to carefully control the critical variables in the implantation process, such as the ion beam energy, ion beam mass, ion beam current (electrical charge per unit time), and ion dose at the target (total number of ions per unit area that penetrate into the target). Further, beam angular divergence (the variation in the angles at which the ions strike the substrate) and beam spatial uniformity and extent must also be controlled in order to preserve semiconductor device yields.

It is advantageous in some applications to tilt the substrate during the implant to allow some dopant to be implanted under the edge of the mask, as illustrated in FIGS. 3, and 4. These tilted implants are sometimes referred to as “halo implants” or “pocket implants”. The tilt angle is as much as 60 degrees. The substrate must be tilted on at least two orthogonal axes both plus and minus angles so four different implant angle directions are accomplished so as to implant under all sides of the masks. This is known a tilted quad implant. It can be advantages to use more than four angles if the layout of the circuits is not on orthogonal grids. The function of the halo or pocket implant is to alleviate the short channel effect and the roll off of the threshold voltage in devices with short channel lengths. It is always of the opposite implant type as the source/drain extension.

An important aspect of modern semiconductor technology is the continuous evolution to smaller and faster devices. This process is called scaling. Scaling is driven by continuous advances in lithographic process methods, allowing the definition of smaller and smaller features in the semiconductor substrate which contains the integrated circuits. A generally accepted scaling theory has been developed to guide chip manufacturers in the appropriate resize of all aspects of the semiconductor device design at the same time, i.e., at each technology or scaling node. The greatest impact of scaling on ion implantation process is the scaling of junction depths, which requires increasingly shallow junctions as the device dimensions are decreased. This requirement for increasingly shallow junctions as integrated circuit technology scales translates into the following requirement: ion implantation energies must be reduced with each scaling step. The extremely shallow junctions called for by modern, sub-0.13 micron devices are termed “Ultra-Shallow Junctions”, or USJ.

Pre-amorphization has been used extensively in the production of ultra shallow junctions in integrated circuits. This step has been required to alleviate channeling of the dopant ions into the major axes and planes of the crystalline silicon, commonly used in CMOS device fabrication. When the energetic ions impact the silicon surface of a target substrate, some of the ion trajectories are parallel to the axes and planes of the silicon crystal. The ions, to which this occurs, travel considerably deeper into the silicon before coming to rest. This phenomenon is known as channeling. Channeling results in a deeper junction than desired.

An implant of a heavy ion has been used to “pre-amorphize” the crystal to prohibit channeling. An amorphous layer created by the pre-amorphizing implant damages the crystalline structure, thus eliminating the paths (axes and planes) that allow channeling of energetic ions. The energy of the pre-amorphization implant is set to produce an amorphous layer of the desired thickness. The dose is determined by the number of ions that are required to sufficiently damage the silicon crystal. Heavier ions require smaller doses to produce the desired damage.

Historically, silicon ions were used to damage the silicon crystal. Silicon was believed to be appropriate for a pre-amorphization implant into a silicon substrate because putting silicon into silicon has no chemical or electrical effect on the material. Argon and Xenon are also known to have been used for such pre-amorphization implants. However, both silicon and argon are relatively low mass ions. As such, the required doses of silicon and argon were relatively high. In order to reduce the dose and therefore the implant time, heavy ions, such as Ge, Sb, In and the like are known to be used for such pre-amorphization implants. Unfortunately, the feed material needed to produce such ions is extremely toxic and drastically reduces the useful life of the ion source.

In general, ion implantation alone is not sufficient for the formation of an effective semiconductor junction. Ion Implantation is always followed by an anneal, a thermal process whereby the substrate is heated to a temperature substantially above room temperature, usually from 600 degrees Celsius to 1300 degrees Celsius. The purpose of the anneal is two-fold: firstly, to activate the dopants and secondly, to repair the damage that is caused by the implantation process. Activation means to make the dopant atom a substitutional impurity, thus allowing it to donate its extra electron, or hole, to the conduction band. In other words the dopant atom takes the place of a silicon atom in the crystal lattice. The repair of damage is required because as the incident ions enter the crystal they can strike silicon atoms and transfer enough energy for that atom to be knocked out of its lattice position thus forming a silicon interstitial and a vacancy in the silicon crystal. It has long been understood that heating the crystal allows for the repair of this kind of crystalline lattice damage.

### SUMMARY OF THE INVENTION

Briefly, the present invention relates to a method of producing ultra shallow junctions for PMOS transistors without the need for pre-amorphization implants by utilizing B₁₈Hₓ⁺ ion implantation to both dope and self- or auto-amorphize a silicon substrate in the region of the source and drain extension. A key element of the present invention is that the pre-amorphizing step may be eliminated, resulting in substantial cost savings in processing a wafer. An appropriate anneal is used to activate the dopant and repair the implant damage. The depth of implantation is controlled by the implant parameters, such as energy, dose and tilt angle. Tilted implants (i.e. “halo” or “pocket” implants) may be used in conjunction with B₁₈Hₓ⁺ source/drain extension implants to place the dopant atoms in the appropriate location to elevate the short channel effect. An appropriate process sequence is utilized that compliments the use of B₁₈Hₓ⁺ ion implantation. The wafer may be tilted during the source/drain extension B₁₈Hₓ⁺ implantation to tailor its profile to enhance transistor performance.

### DESCRIPTION OF THE DRAWINGS

These and other advantages of the present invention will be readily understood with reference to the following specification and attached drawing wherein:

FIG. 1 is a mass spectrum diagram of B₁₈H₂₂ ion beam current as a function of mass in AMU illustrating a peak at a mass of 210 AMU.

FIG. 2 contains depth profiles of ¹⁰B and ¹¹B of exemplary implanted silicon wafers.

FIG. 3 is a side section view of a CMOS integrated circuit transistor showing the parts of interest and where the implants are placed to produce transistors.

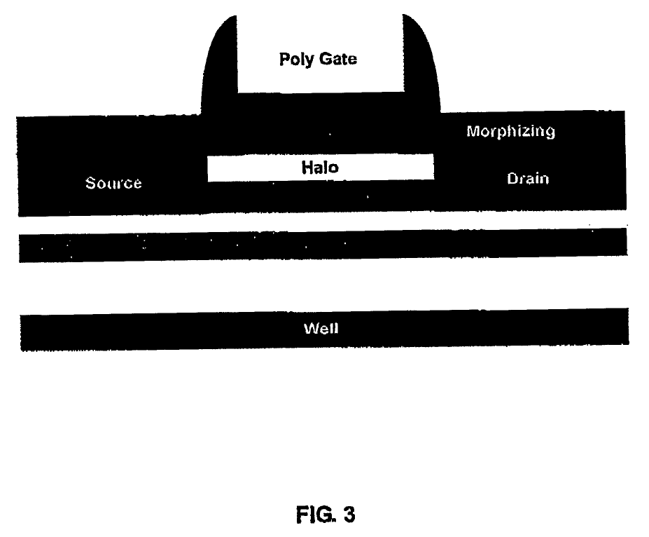

FIG. 4 is a simplified diagram of the CMOS integrated circuit transistor illustrated in FIG. 3 illustrating implantation at an exemplary tilt angle.

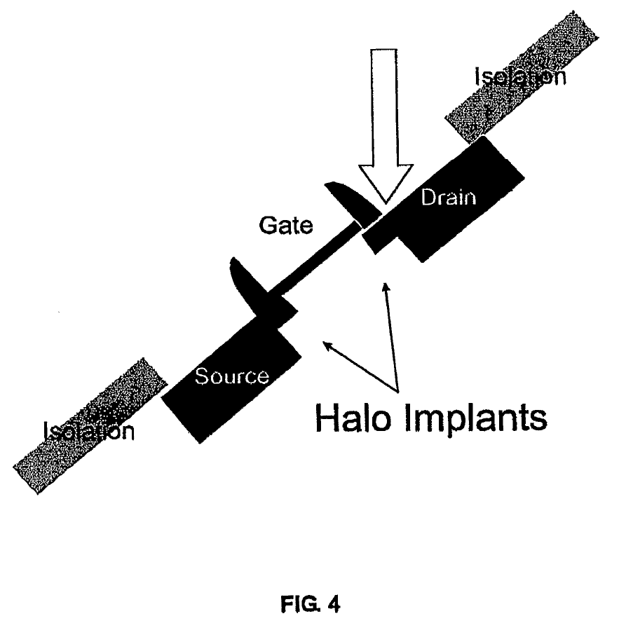

FIG. 5 is an exemplary semiconductor process diagram illustrating implantation of B₁₈Hₓ⁺ cluster ions using exemplary process variables.

FIG. 6 is an exemplary semiconductor process diagram illustrating implantation of B₁₈Hₓ⁺cluster ions at a 0° tilt angle followed by an annealing step.

FIG. 7 is an exemplary semiconductor process diagram illustrating implantation of B₁₈Hₓ⁺ cluster ions at different tilt angles.

FIG. 8 is similar to FIG. 2 after annealing at B₁₈Hₓ⁺ implant energy of 10 keV and B⁺ of 0.5 keV.

FIG. 9 illustrates the junction depth of boron at 1E18/cm³ as implanted and after annealing.

FIG. 10 illustrates the junction depth and sheet resistance of B₁₈Hₓ⁺ and B⁺.

FIG. 11 illustrates the roll-off characteristics of threshold voltage Vₜₕ in pMOSFETS implanted with process equivalent energies and doses of either of B₁₈Hₓ⁺ or B⁺.

FIG. 12 illustrates the I_{ds}-I_{off} characteristics at 1.1 volt for devices implanted with B₁₈Hₓ⁺ at 4, 10 and 16 keV (0.2, 0.5, and 0.8 keV equivalent boron energies, respectively.

### DETAILED DESCRIPTION

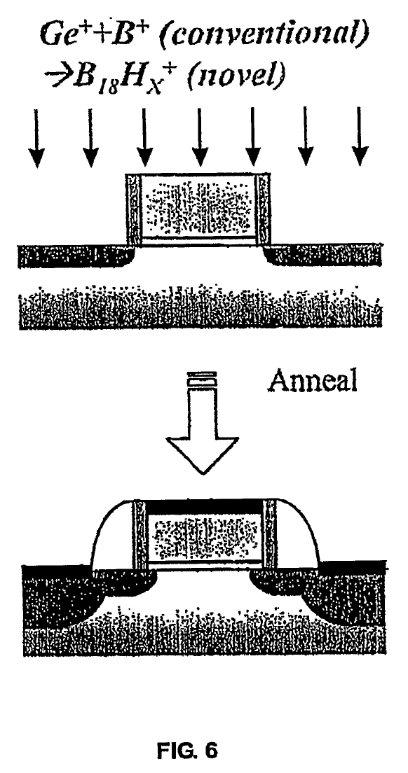

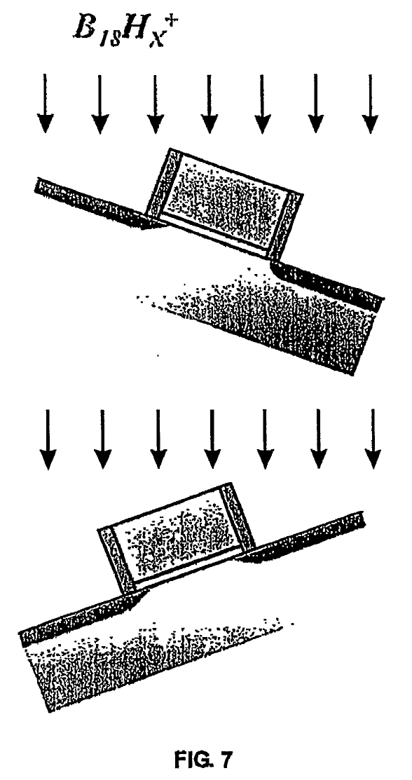

The present invention relates to a method of producing ultra shallow junctions for PMOS transistors without the need for pre-amorphization implants by utilizing B₁₈Hₓ⁺ ion implantation to both dope and self- or auto-amorphize a silicon substrate in the region of the source and drain extension. A key element of the present invention is that the pre-amorphizing step may be eliminated, for example, as illustrated in FIG. 6, resulting in substantial cost savings in processing a wafer. An appropriate anneal is used to activate the dopant and repair the implant damage. The depth of implantation is controlled by the implant parameters, such as energy, dose and tilt angle. Tilted implants (i.e. “halo” or “pocket” implants), for example, as illustrated in FIG. 7, may be used in conjunction with B₁₈Hₓ⁺ source/drain extension implants to place the dopant atoms in the appropriate location to elevate the short channel effect. Furthermore an appropriate process sequence is utilized that compliments the use of B₁₈Hₓ⁺ ion implantation. The wafer may be tilted during the source/drain extension B₁₈Hₓ⁺ implantation to tailor its profile to enhance transistor performance.

### B₁₈Hₓ⁺ Ion Implantation

Due to the aggressive scaling of junction depths in CMOS processing, the ion energy required for many critical implants has decreased to the point that conventional ion implantation systems, which were originally developed to generate much higher energy beams, deliver much reduced ion currents to the wafer, reducing wafer throughput. The limitations of conventional ion implantation systems at low beam energy are most evident in the extraction of ions from the ion source, and their subsequent transport through the implanter's beam line. Significant beam transport limitations occur at ion beam energies below about 10 keV, due to so-called space charge effects. Since scaling has resulted in demand for sub-keV boron (B⁺) implants to create ultra shallow junctions, the beam current, and hence the wafer throughput, of the ion implanter is reduced by as much as an order of magnitude compared with the productivity of the implanter at 10 keV, for example. When implanting B₁₈Hₓ⁺ at approximately 210 AMU, a beam transport energy of 10 keV results in a velocity of the individual boron atoms making up the molecule of only 0.5 keV. Thus, upon implantation into the silicon, the B₁₈Hₓ⁺ ion breaks up into its constituent boron atoms, each with about 1/20^{th} of the energy of the molecule. And, since the beam carries 18X the dose per electrical charge, significant effective boron beam currents (in excess of 10 mA) can be delivered to the wafer at sub-keV boron energies. This results in a very significant increase in throughput, and a drastic decrease in cost per implanted wafer.

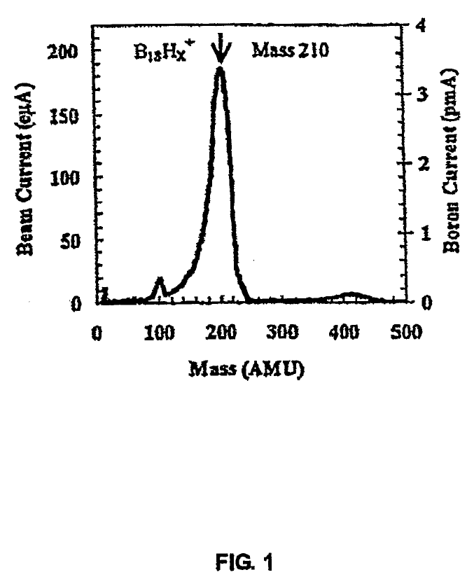

Beam currents for ion implantation are generated from solid octadecaborane, B₁₈H₂₂. FIG. 1 illustrates the mass spectrum of the cluster beam with an extraction voltage of 10 kV. As shown, the distribution ranges from about 200 to 220 AMU, which indicates a wide spectrum of boron cluster ions including both mass 10 and mass 11 isotopes of boron with different numbers of hydrogen atoms bonded to the borohydride molecule are contained in the same mass spectrum. The peak of the distribution is located at 210 AMU. From the viewpoint of beam current and throughput, the mass defining aperture in the ion implantation device should be 15 AMU wide and centered around mass 210, which insures that all of the ions passed are B¹⁸Hₓ⁺ and contains about 89% of the B₁₈Hₓ beam.

The beams may be generated for example with an Axcelis Model no. GSD 100 ion implant device retrofitted with a SemEquip ClusterIon® source and vaporizer. The original boron beam current specification for the above mentioned Axcelis ion implant device is 1 mA at 10 keV. When retrofitted with the SemEquip ClusterIon® ion-source and vaporizer, 4 mA of boron at 500 eV can be delivered to the wafer.

The generation of B₁₈Hₓ⁺ ions for ion implantation requires a specialized ion source which converts gaseous B₁₈H₂₂ vapor into B₁₈Hₓ⁺ ions in an efficient manner which is compatible with the ion implantation system. Such a source is described in U.S. Pat. Nos. 6,452,338, 6,686,595, and 6,744,214, for example, hereby incorporated by reference. The source described in the aforementioned patents includes a vaporizer for vaporizing solid borohydride material, such as decaborane (B₁₀H₁₄), and flowing the vapor into a chamber which ionizes the vapor molecules by electron-impact ionization. This “soft” ionization technique insures that the parent molecule is preserved without substantial dissociation during the ionization process. Octadecaborane (B₁₈H₂₂) can be ionized to form B₁₈Hₓ⁺ ions by the same or similar process, since B₁₈H₂₂ is also a solid borohydride material.

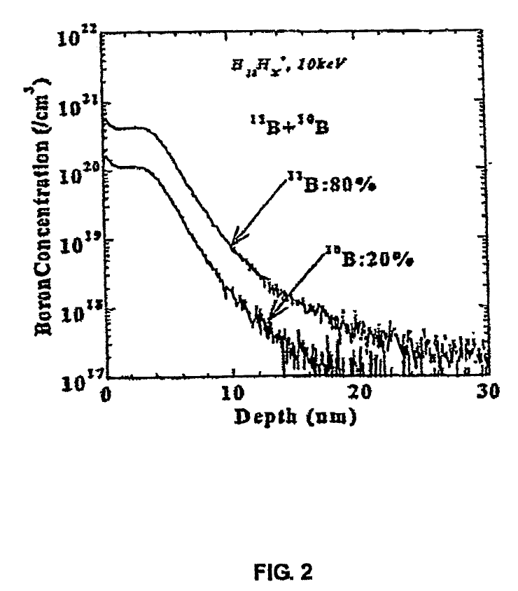

With the beam optimized, a 15 AMU wide portion of the beam around mass 210 AMU is selected for implantation. Exemplary implantations were performed at 200 eV, 500 eV and 800 eV equivalent energies with a process equivalent dose of 3×10¹⁴ B/cm² correspond to extraction voltages of 4 kV, 10 kV and 16 kV with an electrical dose of 1.67×10¹³/cm². FIG. 2 illustrates the depth profile of boron in an as implanted wafer with an extraction voltage of 10 kV (500 eV implant energy). FIG. 2 also illustrates that in addition to ¹¹B, ¹⁰B is also implanted. The ¹⁰B dose calculated from the profile is 20% of the total dose and ¹¹B is 80%. This is a result of the natural abundances of ¹⁰B and ¹¹B, which are 20 & and 80% respectively.

In order to form the ultra shallow junctions, a cluster ion implant of B₁₈Hₓ is implanted for the source or drain extension, immediately after the PMOS masking is complete. These clusters produce sufficient damage to the crystal to induce amorphization. This is known as auto-amortization or self-amorphization. Due to the mass of the cluster and the fact that all 40 of its atoms arrive at the surface of the silicon simultaneously, this sufficient damage accumulates early enough in the process to prevent most channeling. This eliminates the need for a separate step to pre-amortizing the silicon with a heavy energetic ion. The implanted substrate must be followed by an anneal to repair the substrate and to activate the dopant

### EXEMPLARY EMBODIMENT

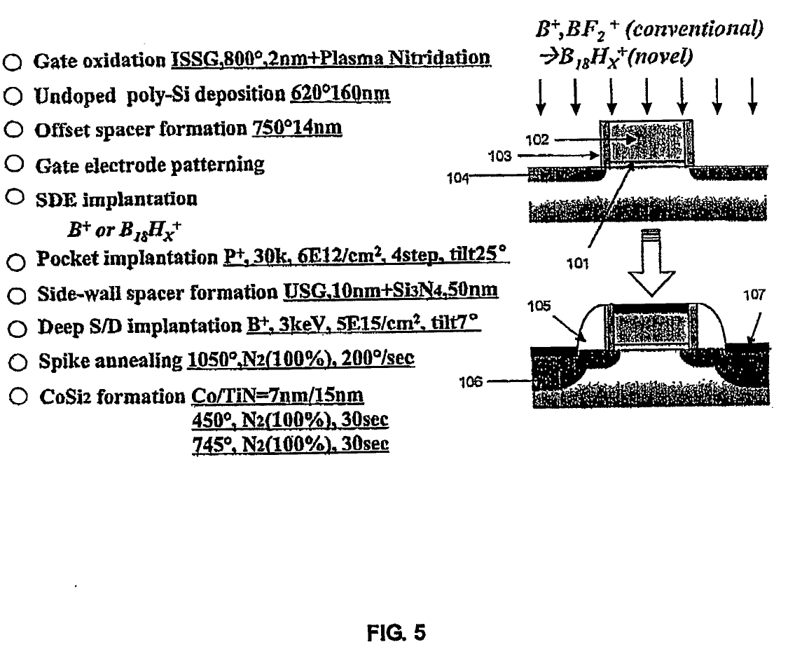

An exemplary application of the present invention is illustrated in FIG. 5 with exemplary process variables. The first step is to grow a nitrided gate oxide [101] that will from the insulator in the gate stack. The second step is to deposit the poly silicon for the gate stack [102]. The third step is to form the vertical gate spacer [103] necessary to obtain the correct dopant profile in the channel. This is followed by the patterning of the gate area. The fifth step is the actual ion implantation of the source/drain extension [104] with B⁺ or B₁₈Hₓ⁺ ions. The next step is the pocket implant to tailor the channel doping to eliminate the short channel effect. This step uses the same masking as the source/drain extension implant. The seventh step is to deposit the sidewall spacer [105] to provide adequate isolation between the gate stack and the source/drains. The eighth step is the implantation of the deep source/drains with B⁺ or B₁₈Hₓ⁺ ions. This implant step is followed by an anneal to activate the extensions and the deep source/drain regions. Lastly the metal contacts [107] are deposited.

Various implant energies can be used for the B₁₈Hₓ⁺ source drain extension Implants, such as 4 keV, 10 keV and 16 keV. In an alternate embodiment, pre-annealing may be done before side-wall formation in order to suppress the damage due to the cluster ion implantation. Pre-annealing may be conducted at 200° C.-600° C. for 60 minutes or more or at 600° C.-900° C. with a ramp rate of 50° C./second with a zero dell time in a nitrogen environment.

In order to optimize the pocket implantation, phosphorous is normally matched to the same implant energy of the B₁₈Hₓ⁺. Thus, if the implant energy of the B₁₈Hₓ⁺ is 0.8 keV, the implant parameters of phosphorous are: implant energy=30 keV; dose=6E12/cm² and tilt=7. For implant energies of B₁₈Hₓ⁺<0.8 keV, the implant parameters of the phosphorous (i.e. energy, dose and tilt angle) are adjusted to obtain a deeper phosphorous profile.

The source/drain extension implants can be accomplished with the wafer in a tilted position to further profile the dopant in the channel. This implant could be as steep as 60 degrees. This implant would further be required to be carried out in the quad mode so that all sides of the devices are equally implanted. This type of tilted source/drain extension implant is particularly advantages when advanced annealing techniques, which severely limit the lateral diffusion under the gate, are incorporated into the processing sequence.

### Performance Characteristics

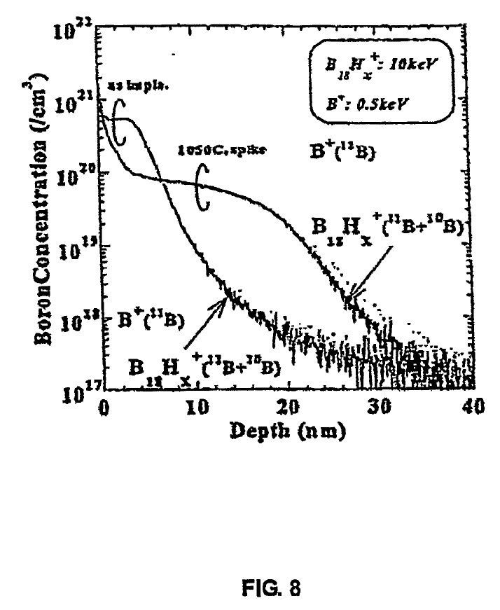

FIG. 8 illustrates the boron profiles for both pre- and post-annealing of a 10 keV (0.5 keV process equivalent) B₁₈Hₓ⁺ implant and a 0.5 keV B⁺ implant. The profile of B₁₈Hₓ⁺ is plotted as the sum of ¹¹B and ¹⁰B, while the B⁺ implant is only the ¹¹B. The ¹⁰B of the monomer implant can be neglected because the BF₃ source used is ¹¹B isotopically enriched. The B₁₈Hₓ⁺ profiles are steeper and shallower than the profiles of the B⁺ due to the auto-amorphization caused by the large boron cluster. Once the substrate crystal becomes amorphous, ion channeling is no longer possible, thus reducing the channeling tail in the B distribution. During annealing, boron redistribution occurs due to the high thermal budget for both B₁₈Hₓ⁺ and B⁺ implants. However, the B profile from the B₁₈Hₓ⁺ implants is in all cases shallower than from B⁺ implants.

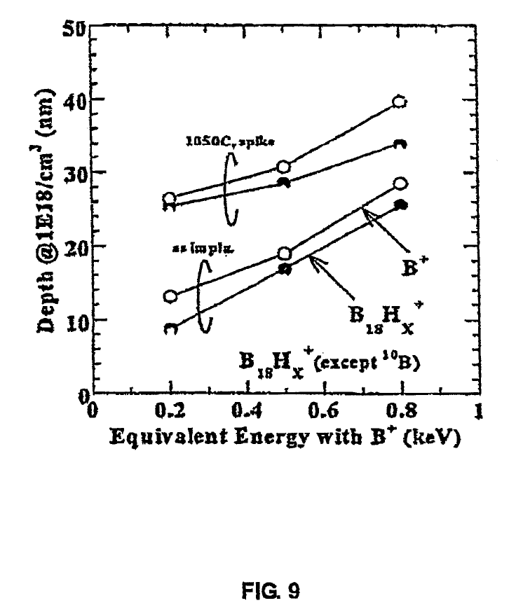

The boron junction depth for each condition is shown in FIG. 9. The depth is defined as the distance below the surface where the concentration of B is 1×10¹⁸/cm³ as measured by SIMS. The energy of the B₁₈Hₓ⁺ implantation is converted to the equivalent process energy and is identical to the B⁺ implant energies. In the case of B₁₈Hₓ⁺, the mass 10 and 11 profiles are added as described above to obtain a total B concentration.

The as-implanted junction depths from B₁₈Hₓ⁺ implants are shallower than the B⁺ monomer implants at all three energies. As the implant energies decrease, the junction depth of B₁₈Hₓ⁺ implants decrease as expected. The only exception is for the 0.2 keV B⁺ implants, done in a deceleration mode, where energy contamination causes the B profiles to be extended on the high-energy side of the distribution, thus pushing out the junction depth.

Post-annealing diffusion lengths of B₁₈Hₓ⁺ are similar to the B₁₈Hₓ⁺ implants diffusion lengths except for the 0.2 keV implants. All annealed B₁₈Hₓ⁺ implants have shallower junction depths than B₁₈Hₓ⁺ implants at equivalent energies and doses.

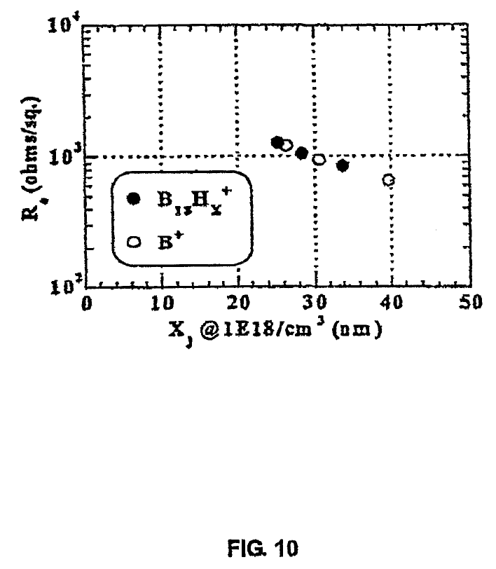

FIG. 10 shows sheet resistance R, vs. junction depth Xⱼ for both B₁₈Hₓ⁺ and B⁺ implants at 0.2, 0.5 and 0.8 keV process equivalent energies after a 1050° C. spike anneal. The junction depths after annealing are from FIG. 9. The sheet resistance data was obtained from four-point probe measurements. This data is plotted on the trade-off curve of B, which indicates that the carrier concentration of Si implanted with B₁₈Hₓ⁺ is nearly identical to that of Si implanted with B⁺ at process equivalent energies and doses.

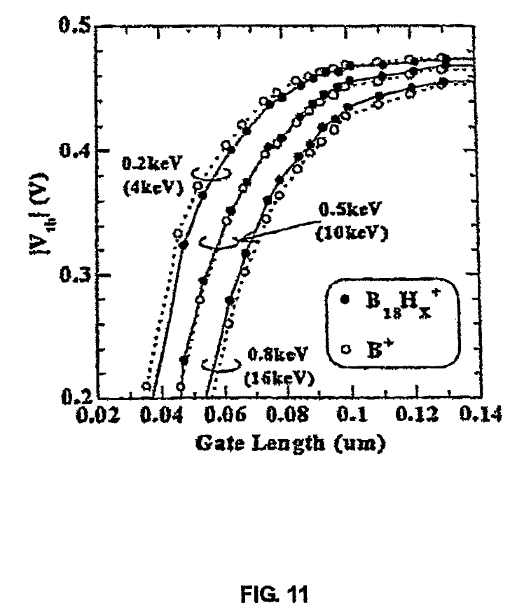

FIG. 11 illustrates the roll-off characteristics of Vₜₕ in pMOSFETS implanted with process equivalent energies and doses of either B₁₈Hₓ⁺ or B⁺. The short channel effect in these devices may be improved by lowering the energy from 0.8 keV to 0.2 keV for both types of implants. The shift of the curve with the lowering of the energy of the B₁₈Hₓ⁺ is a little smaller than that of B⁺. This tendency is consistent with the shift of the depth between B₁₈Hₓ⁺ and B⁺, as shown in FIG. 9.

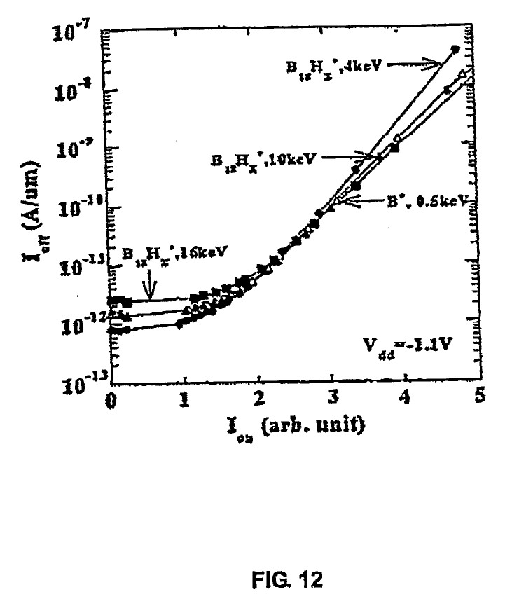

FIG. 12 illustrates the I_{ds}-I_{off} characteristics at 1.1 volts for devices implanted with B₁₈Hₓ⁺ at 4, 10 and 16 keV (0.2, 0.5 and 0.8 keV equivalent energies, respectively) as well as B⁺ at 0.5 keV, all with equivalent boron doses of 3×10¹⁴/cm². The I_{ds}-I_{off} curve of B₁₈Hₓ⁺ at 10 keV (0.5 keV) has the same characteristics as that of B⁺ implants at an equivalent energy. The drain current of the B₁₈Hₓ⁺ and B⁺ implanted devices are the same at the off-state leakage current of 20 pA/μm though the I_{ds}-I_{off} curves of B₁₈Hₓ⁺ are different from each other on the whole.

Obviously, many modifications and variations of the present invention are possible in light of the above teachings. Thus, it is to be understood that, within the scope of the appended claims, the invention may be practiced otherwise than as specifically described above.

We claim:

1. A method for forming ultrashallow junctions in a semiconductor substrate, the method comprising the steps of:
(a) providing a semiconductor substrate with a crystalline structure:
(b) selecting a first dopant ion species for implantation into said semiconductor substrate, said first dopant ion species selected to damage the crystalline structure of said semiconductor substrate upon implantation into said semiconductor substrate;
(c) implanting said first dopant ion species into a selected location on said semiconductor substrate at a predetermined energy and dose selected to form an ultrashallow junction; and
(d) annealing said selected location of said semiconductor substrate.

2. The method as recited in claim 1, wherein step (a) comprises:
(a) providing a silicon substrate.

3. The method as recited in claim 1, wherein step (b) comprises:
(b) selecting a boron cluster ion as a dopant ion.

4. The method as recited in claim 3, wherein step (b) comprises:
(b) selecting a boron hydride cluster ion as a dopant ion.

5. The method as recited in claim 4, wherein step (b) comprises:
(b) selecting octadecaborane as a dopant ion.

6. The method as recited in claim 4, wherein step (b) comprises:
(b) selecting decaborane as a dopant ion.

7. The method as recited in claim 1, further comprising the steps:
(e) tilting said semiconductor substrate to a predetermined angle; and
(f) implanting a second dopant ion species at said tilt angle.

8. The method as recited in claim 7, wherein step (f) comprises:
(f) implanting a second dopant ion species that is different from said first dopant ion species.

9. The method as recited in claim 8 wherein step (f) comprises:
(f) implanting phosphorous dopant ions.
